(19) United States
(12) Patent Application Publication
(10) Pub. No.: US 2019/0115377 A1
(43) Pub. Date: Apr. 18, 2019

(54) IMAGING SENSOR

(71) Applicant: EXPANTRUM OPTOELECTRONICS, SHANGHAI (CN)

(72) Inventor: Zhongshou HUANG, SHANGHAI (CN)

(73) Assignee: EXPANTRUM OPTOELECTRONICS, SHANGHAI (CN)

(21) Appl. No.: 16/018,207

(22) Filed: Jun. 26, 2018

(30) Foreign Application Priority Data
Oct. 18, 2017 (CN) 201710972500.5

(51) Int. Cl. H01L 27/146; H05G 1/10

(52) U.S. Cl. CPC H01L 27/14603; H05G 1/10; H01L 27/14643

(57) ABSTRACT

An imaging sensor including a pixel array having a plurality of pixels, the pixel comprises a first photodiode serious connected to a second photodiode to form a photodiode chain, wherein a first terminal of the photodiode chain is coupled to a first voltage source; a signal output transistor including a gate terminal coupled to a first scan line, a drain terminal coupled to an amplifying transistor and a source terminal coupled to a signal output path, wherein the amplifying transistor includes a gate terminal coupled to a second terminal of the photodiode chain and a drain terminal coupled to an external power source; and a first reset transistor including a gate terminal coupled to a second scan line, a source terminal coupled to the second terminal of the photodiode chain and a drain terminal coupled to a second voltage source.

### CROSS REFERENCE

This application is based upon and claims the benefit of priority of Chinese Patent Applications No. 201710972500.5, filed on Oct. 18, 2017, the entire contents thereof are incorporated herein by reference.

### TECHNICAL FIELD

The present disclosure relates to the field of photoelectric technology, specifically to an imaging sensor including functions of amplifying output signals of a pixel circuit by increasing photoelectric conversion voltage.

### BACKGROUND

In recent years, with rapid developments of active matrix liquid crystal display (AMLCD) technology, thin film transistors and functional thin film technologies are widely applied in various fields. In particular, the thin film transistor (TFT-Thin Film Transistor) active matrix has been applied to flat panel X-ray imaging device, for the reason that X-ray cannot been deflected by a glass lens system. With the development of the TFT matrix technology, semiconductor thin films including P-type dopant or N-type dopant are formed, by deposition process, on a large-area substrate for meeting various requirements of applications. The substrate includes a transparent glass substrate or a stainless steel substrate or flexible substrates including organic thin films.

There are two types of the X-ray imaging sensor, the first type is so called indirect conversion X-ray image detector. The indirect conversion X-ray image detector includes a layer of a photoelectric conversion film. The photoelectric conversion film, including a hydrogenated amorphous silicon photodiode film, is formed, by the deposition process, on the TFT pixel array. The photodiode is capable of converting incident photons into electron and holes. The photoelectric conversion film is then covered with a material, including a phosphor film or a scintillattor film, which is capable of converting incident X-rays into visible light photons, that the name “indirect” is therefore originated. Compared with a traditional X-ray sensitive film or fluorescent plate on CCD camera system, this indirect conversion flat panel X-ray image detector has exhibited various advantages including real-time digital imaging, higher sensitivity or lower dosage to patients in another words, and a compact size.

The second type of the X-ray image detector is so called direct conversion X-ray image detector. The direct conversion X-ray image detector includes a semiconductor photoconductive thin film, e.g. a-Se or PbO, for converting incident X-ray into electrons and holes that can be directly treated as signal. The direct conversion X-ray image detector has a rather simple structure, that the electrons and holes, as image data carrier, are driven by electric field straightly to colleting, electrode without diffusion and scattering as what happening as the light transferring in a scintillator film. This direct conversion structure exhibits no image blur. However, direct conversion X-ray image detectors have an obvious disadvantage of requiring high driving voltage in proportional to the thickness of the X-ray conversion film.

Each pixel of the flat panel image sensor includes a photoelectric conversion unit and a switching TFT, for outputting signal charges, and does not include signal amplification and noise cancelation functions. When a small amount of photogenerated charges are transmitted to a preamplifier in peripheral circuits via an data line, the photogenerated charges will be mixed with various noise sources including the thermal noise of the data line, the leakage current noise of switching transistors linked to the data line, and the switching noise of the switching TFT.

If the photogenerated signal is amplified inside the pixel prior to be transmitted to the data line, interferences, caused by various noise, are avoided and the sing to noise ratio of the image signal will be significantly increased. An imaging sensor with amplifying function is called Active Pixel Sensor or APS, where the signal amplifying and noise cancelation circuits are formed together with the photoelectric converting portion on the same substrate.

FIG. 1 shows a prior art of pixel circuits of flat panel X-ray image sensor without amplifying function. As shown in FIG. 1, the pixel circuit includes a photodiode PD₁ and a switching TFT N₁. Data₁ and Data₂ present data lines of two adjacent pixels respectively. FIG. 2 shows a prior art of a typical APS pixel circuit that includes three transistors and one photodiode. As shown in FIG. 2, transistor M₁ is a reset transistor, transistor M₂ is an amplifying transistor and M₃ is a gate transistor, PD₁ is a photodiode and Vout₁ is output signal voltage of the pixel. As shown in FIG. 1 and FIG. 2, Scan 1 is a first scan line and Scan 2 is a second scan line following the scanning direction of the image array. As shown in FIG. 2, the photogenerated charges are converted into signal voltage at the gate node of the amplifying transistor M₂ in inversely proportional to the total capacitance at the gate node. When the output switch M₃ is turned on, the drain current of the transistor M₂ or its gate voltage is read out. Therefore, the output signal voltage or signal current increases as the total capacitance at the gate node decreases, roughly in an inverse proportional relation.

The photodiodes in a flat panel X-ray detector are usually made of hydrogenated amorphous silicon a-Si:H thin films in a permittivity of approximately 12.9. If the film thickness of the photodiode is 2.0 μm, the capacitance is about 5.8 nF/cm². For a 100 μm×100 μm amorphous silicon photodiode the capacitance of is about 0.58 pF. The total capacitance at the gate node, including the capacitance of the photodiode and the capacitance of the gate terminal of the amplifying transistor M₂ and the capacitance of the source terminal of the reset transistor M₁, is approximately approaching to 0.8 pF. At the room temperature the switching noise (KTC noise) alone is equal to nearly 360 electrons. In other words, signals less than 360 electrons are buried by switching noise and no longer detectable. Therefore it is the primary objectives of this invention to significantly decrease the total capacitance at the gate node.

### SUMMARY

in one embodiment of the present disclosure, an imaging sensor including a pixel array having a plurality of pixels, the pixel comprising a photodiode chain comprising a first photodiode and a second photodiode connected in series, wherein the first terminal of the photodiode chain is connected to a first voltage source. The pixel further includes an amplifying transistor having a gate electrode connected to the second terminal of the photodiode chain, a first reset transistor having a gate electrode connected to a second scan line, having a source electrode connected to the gate electrode of the amplifying transistor, having a drain electrode connected to a second voltage source, and an output transistor having a gate electrode connected to a first scan line, and having a source electrode connected to the amplifying transistor, having a drain electrode connected to an output data line.

### BRIEF DESCRIPTION OF THE DRAWINGS

Embodiments of the present disclosure will now be described, by way of example only, with reference to the accompanying schematic drawings in which corresponding reference symbols indicate corresponding parts, and in which:

FIG. 1 shows a schematic view of a pixel circuit of a X-ray imaging sensor without amplifying function;

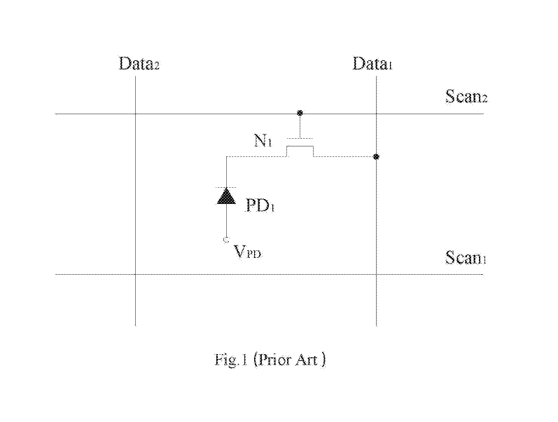

FIG. 2 shows a schematic view of a pixel circuit of a X-ray imaging sensor with amplifying function;

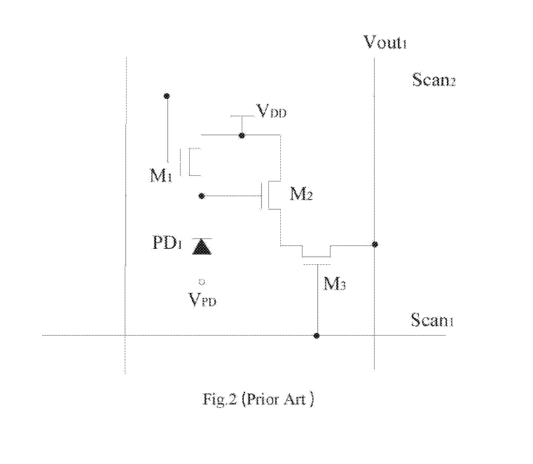

FIG. 3 shows a schematic view of a pixel circuit of an imaging sensor of one embodiment of the present disclosure;

FIG. 4 shows a schematic view of an equivalent circuit of a photodiode chain of FIG. 3 of one embodiment of the present disclosure;

FIG. 5 shows a diagram of a band distribution of the photodiode chain of FIG. 3 of one embodiment of the present disclosure;

FIG. 6 shows a schematic view of a pixel circuit of an imaging sensor of one embodiment of the present disclosure;

FIG. 7 shows a schematic view of a pixel circuit of an imaging sensor of one embodiment of the present disclosure;

FIG. 8 shows a schematic view of a pixel circuit of an imaging sensor of one embodiment of the present disclosure;

FIG. 9 shows a schematic view of a pixel circuit of an imaging sensor of one embodiment of the present disclosure;

FIG. 10 shows a schematic view of a pixel circuit of an imaging sensor of one embodiment of the present disclosure;

FIG. 11 shows a schematic view of a pixel circuit of an imaging sensor of one embodiment of the present disclosure;

FIG. 12 shows a schematic view of a pixel circuit of an imaging sensor of one embodiment of the present disclosure;

FIG. 13 shows a schematic view of a pixel circuit of an imaging sensor of one embodiment of the present disclosure;

FIG. 14 shows a schematic view of a photodiode chain of an imaging sensor of one embodiment of the present disclosure;

FIG. 15 shows a schematic view of a photodiode chain and a first reset transistor of an imaging sensor of one embodiment of the present disclosure;

FIG. 16 shows a schematic view of a photodiode chain and an amplifying transistor of an imaging sensor of one embodiment of the present disclosure; and

FIG. 17 shows a schematic view of an imaging sensor of one embodiment of the present disclosure.

### DETAILED DESCRIPTION

The features, structures or characteristics described can be combined in any appropriate way in one or more embodiments. In the description below, many specific details are provided to explain the embodiments of the present disclosure fully. However, the technicians in the art should realize that, without one or more of the specific details, or adopting other methods, components, materials etc., the technical proposal of the present disclosure can still be realized. In certain conditions, structures, materials or operations well known are not shown or described in detail so as not to obfuscate the present disclosure. The technical contents of the present disclosure will be further described below with reference to the figures and embodiments. It should be stated that a plurality of embodiments described below along with their combinations and varieties, beyond doubt are within the scope of the present disclosure. Same reference signs in the figures refer to same or similar structures, so repeated description of them will be omitted.

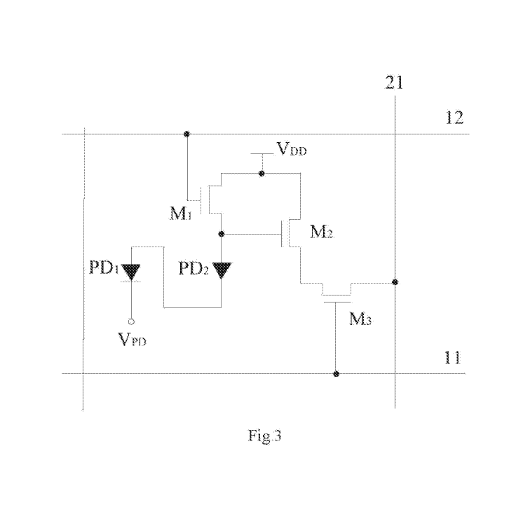

FIG. 3 shows a schematic view of a pixel circuit of an imaging sensor of one embodiment of the present disclosure. In this embodiment, the imaging sensor includes a pixel array (not shown here) having a plurality of the pixels. As shown in FIG. 3, the pixel circuit includes a photodiode chain, comprising a first photodiode PD₁ and a second photodiode PD₂ connected in series. The anode of the first photodiode PD₁ is connected to the cathode of the second photodiode PD₂. A reset transistor M₁ is configured to reset the potential of the photodiode chain in response to a scanning pulse delivered through a second scan line 12.

An amplifying transistor M₂ is configured to convert photogenerated charges in the photodiode chain to a current signal or a voltage signal. An output transistor M₃ is configured to output the current signal or the voltage signal of the amplifying transistor M₂ in response to a scanning pulse delivered through the first scan line 11. In this embodiment, a scanning sequence is arranged that M₃ is turned on first and then M₁ is turned on, to ensure completion of the data output prior to pixel reset. In this embodiment, the three transistors in each pixel are made of NMOS transistor.

In this embodiment, as shown in FIG. 3, the cathode of the first photodiode PD₁ is connected to a first voltage source V_{PD}. The source terminal of the reset transistor M₁ is coupled to the anode of the second photodiode PD₂ and the gate terminal of the amplifying transistor M₂. The drain terminal of the first reset transistor M₁ is connected to a second voltage source V_{DD}. The source terminal of the amplifying transistor M₂ is connected to the drain terminal of the output transistor M₃. The drain terminal of the amplifying transistor M₂ is connected to the second voltage source V_{DD}.

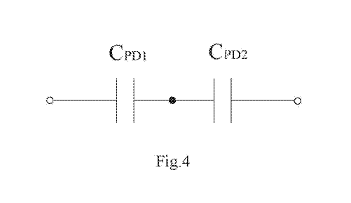

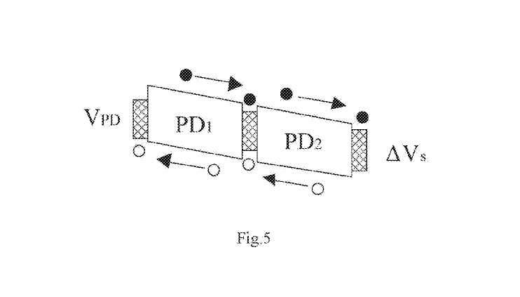

FIG. 4 shows a schematic view of an equivalent circuit of -^{a}\check{}#photodiode chain in FIG. 3. The capacitances of the two photodiodes PD₁ and PD₂ are C_{PD1} and C_{PD2} respectively. FIG. 5 shows a diagram of the energy hand profile of the photodiode chain in FIG. 3. As shown in FIG. 5, ΔVₛ is the output signal voltage of the photodiode chain, resulting from photogenerated charges in both PD₁ and PD₂. As one of the embodiment of this disclosure, the a-Si:H photodiode film in each pixel is divided equally into two areas by lithography process, and then the two areas are connected in series to form the photodiode chain as shown in FIG. 3, FIG. 4 and FIG. 5. Therefore, the effective capacitance of the photodiode PD₁ or PD₂ is then reduced to a half of the original photodiode capacitance before the division, which means C_{PD1}=C_{PD2}=0.5 C_{PD}, where the CP_{D} represents the original capacitance of a photodiode before the division. Similarly the quantity of the photogenerated charge in each divided photodiode is reduced to 0.5 Q_{PD}, where the Q_{PD} represents the original quantity of the photogenerated charge in the photodiode before the division.

The voltage changes on the M₂ gate, or the detection node, is calculated according to the described parameters,

$$Δ {V}_{S 2} = \frac{0.5 {Q}_{PD}}{0.25 {C}_{PD }} = \frac{2 {Q}_{PD}}{{C}_{PD}} = 2 Δ {V}_{S 1}$$

The ΔV_{S1} is the signal voltage of the photodiode before division. The ΔV_{S2} is the signal voltage of the photodiode chain after division. Consequently, for the same quantity of incident photon, the signal voltage at the detection node is doubled. The numbers of photogenerated charges in PD₁ and PD₂ are essentially equal in order to maintain a stable imaging operation.

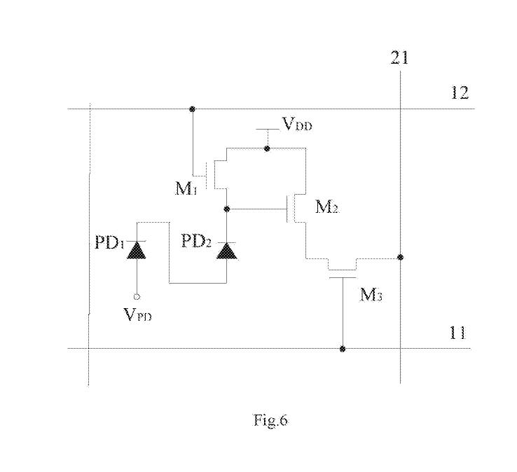

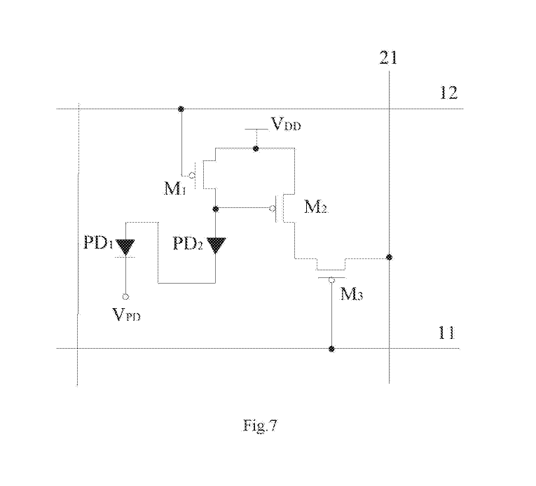

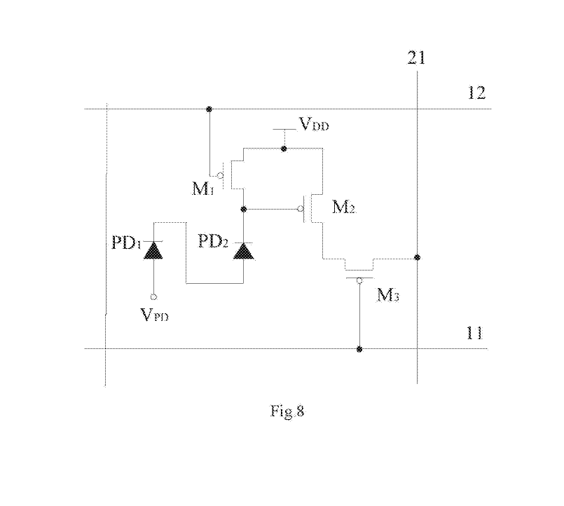

Pixel circuits shown in FIG. 6, FIG. 7 and FIG. 8 are varieties of circuit in FIG. 3 as different embodiments of this disclosure. The pixel circuit of FIG. 6 is similar to the pixel circuit of FIG. 3 but with reversed connection sequence of the two photodiodes. Pixel circuits shown in FIG. 7 and FIG. 8, are different from circuits in FIG. 3 and FIG. 6, employ PMOS transistors for all the three transistors in the pixels.

One condition, for maintaining a stable imaging operation in the above embodiments, is that the two divided photodiodes have equal quantity of the photogenerated charges and equal values of diode capacitance. In other words, by satisfying the assumption, the potential at the joined node of the two photodiode will be kept in the mean value of V_{PD} and the potential of the detection node, or the bias voltages of the two photodiodes are kept at the same value. However, due to variations in manufacture processes, the photocurrent, dark current and equivalent capacitance of one photodiode maybe slightly different from the other's, causing discrepancy in effective diode bias and charges trapping at the joint-node of the two photodiodes. Un-even diode bias will cause an insufficient photoelectric conversion in the photodiode Which has reduced bias voltage. Charge trapping will lead to incompletion of pixel reset and consequently image lags.

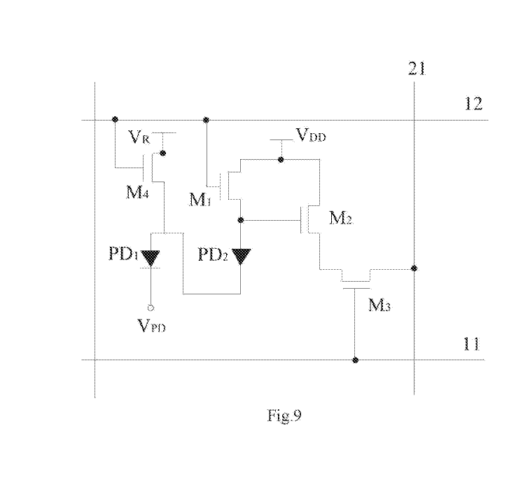

To avoid the un-even diode bias and the associated detrimental effects described above. FIG. 9 discloses a schematic view of a pixel circuit of an imaging sensor of one embodiment of the present disclosure. As shown in FIG. 9, a second reset transistor M₄ is added to the circuit in FIG. 3, that periodically reset the potential of the joint-node of the two photodiode to an voltage source V_{R}. The second reset transistor M₄ is gated by the second scan line 12, similar as the first reset transistor M₁. To ensure the two photodiodes are evenly biased, the three voltage sources are essentially satisfied the following formula:

V_{DD}−V_{R}=V_{R}−V_{PD}

In general, the bias voltage on each photodiode in a photodiode chain should be essentially equal to an average voltage (V_{PD}−V_{DD})/N, where N is the quantity of the photodiodes connected in series. A less strict criteria is that the discrepancy of diode bias from the average voltage should be less than 30% of the average bias.

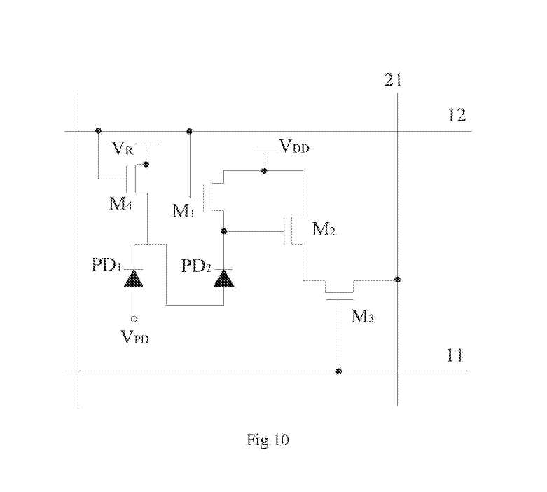

FIG. 10 shows an alternative circuit design having the connection sequence of photodiode chain reversed as an embodiment of this disclosure. Other varieties or combinations such as replacing all the NMOS transistors in FIG. 9 with PMOS transistors or replacing partially with PMOS transistors are all within the scope of the present disclosure.

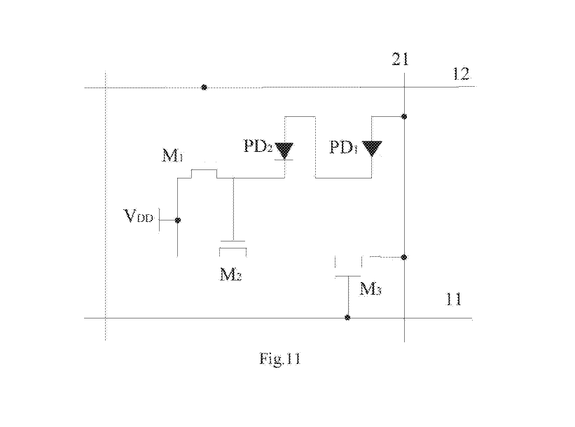

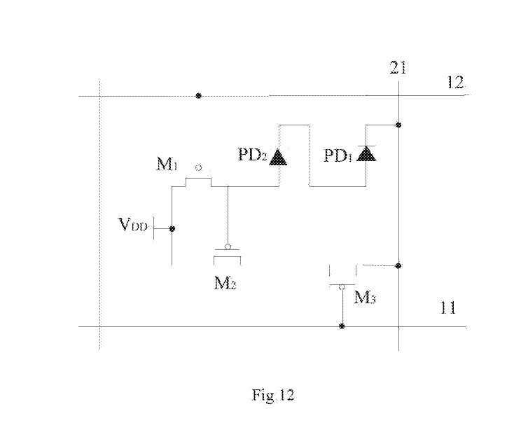

FIG. 11 shows a schematic view of a pixel circuit of an imaging sensor of one embodiment of the present disclosure. FIG. 12 shows an alternative circuit design comparing to the circuit in FIG. 11, by using PMOS transistor and having the connection sequence of the photodiode chain reversed. As shown in FIG. 11 and FIG. 12, the external terminal of the photodiode chain is connected to the data line 21 directly, which suggests that the photodiode chain is biased from external preamplifier of the data line 21. This configuration can be realized since the reset current of the photodiode chain is significantly smaller than a drain current of the amplifying transistor M₂. In other words, embodiment with this circuit configuration, interferences to output signal by the reset current is negligible. The main advantage is no need for a separate external voltage source for the photodiode bias, and then the layout is simplified and some space that would be occupied by external voltage source line can be returned to photodiode sensing area.

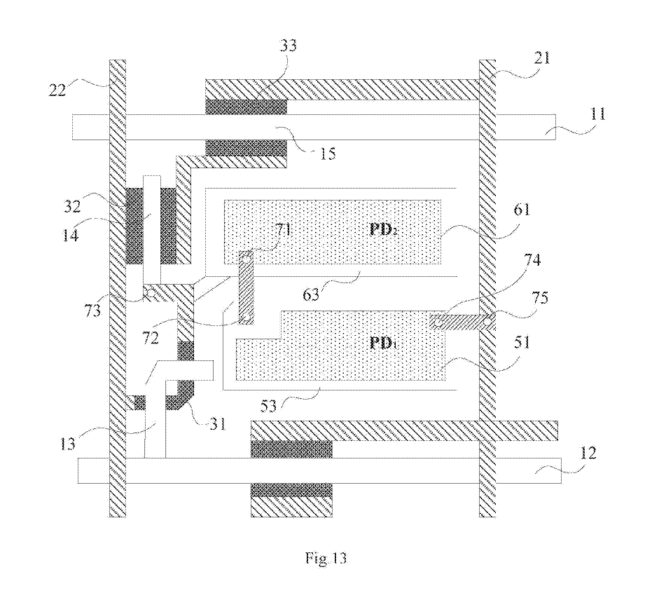

FIG. 13 shows a schematic view of a pixel layout of an imaging sensor of one embodiment of the present disclosure. As shown in FIG. 13, in this embodiment, the data line 21 is configured to provide the photodiode 53 and 63 the external voltage source. Each pixels of the imaging sensor includes the first scan line 11, the second scan line 12, the first photodiode PD₁, the second photodiode PD₂, the first reset transistor M₁ comprising a gate electrode 13 and a semiconductor layer 31, the amplifying transistor M₂ comprising a gate electrode 14 and a semiconductor layer 32, the output transistor M₃ comprising a gate electrode 15 and a semiconductor layer 33, the data line 21 and a power line 22. As shown in FIG. 13, the data line 21 is arranged across the first scan line 11 and the second scan line 12, the power line 22 is arranged in parallel to the data line and across the first scan line 11 and the second scan line 12. In this embodiment, the power line 22, which provides the second voltage source V_{DD}, is connected to the drain tab of the first reset transistor M₁ and the drain tab of the amplifying transistor M₂. Other alternative layouts, such as running the power line 22 in parallel to the scan lines and orthogonal to the data lines are feasible and within the scope of the present disclosure.

As shown in the FIG. 13 layout, the data line 21 is connected to the drain tab of the output transistor M₃, and a first electrode 51 of the first photodiode 51 through a via 74 and a via 75. The power line 22 provides current to the amplifying transistor M₂ and provides a reset voltage to the first reset transistor M₁. The second electrode 53 of the first photodiode PD₁ is connected to the first electrode 61 of the second photodiode PD₂ via the via 71 and the via 72. A second electrode 63 of the second photodiode PD₂ is directly connected to the gate electrode 14 of the amplifying transistor. Any changes in the voltage of the electrode 63 of photodiode PD₂ will then modify the channel current of the amplifying transistor M₂.

Moreover, the second electrode 63 of the second photodiode PD₂ is further connected to the source terminal of the reset transistor M₁ via a via 73. In this embodiment, the transistor M₁, M₂ and M₃ are made of semiconductor thin films, dielectric films and metal layers. The semiconductor thin films include hydrogenated amorphous silicon film, polysilicon film or metal oxide compound film such as In—Ga—Zn—O systems. The mobility of the metal oxides alloys and the low temperature polysilicon (LTPS) range from 20 to 100 cm²/v.s. provide sufficient signal gain for high sensitive image sensors. To reduce leakage current of the reset transistor M1 made of UPS, two identical TFTs are connected in series and driven by the gate metal tab 13.

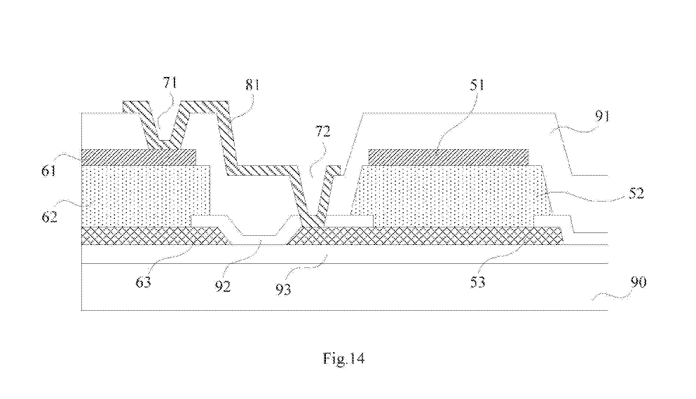

FIG. 14 shows a cross-sectional view of the photodiode chain of the pixel shown in FIG. 13, in this embodiment, each photodiode is made of multiple layer structure, comprising p+ doped layer, intrinsic layer and n+ doped layer, or PIN diode structure, for the sake of simplicity. The two photodiodes have equal light receiving area and capacitance. As shown in FIG. 14, the photodiodes are fabricated on a substrate 90, which can be made of a transparent glass or a flexible stainless steel plate or organic materials. A third insulation layer 93 serves as a gate insulation film of the thin film transistor (not shown in FIG. 14). A second conducting layer is deposited on the insulation layer 93 for the second electrode 53 which servers as the bottom electrode of the first photodiode PD₁ and the second electrode 63 which servers as the bottom electrode of the second photodiode P1 ₂. In this embodiment, the electrode materials include materials of Mo, Cr, or Cu. A majority portion of each semiconductor thin film 52 and 62 contact directly to the electrodes 53 and 63, respectively.

The second insulation layer 92 wraps the edges of the second electrodes 53 and 63 as illustrated in FIG. 14, aiming to minimize the leakage current at the electrode edges. A first electrode 51 and a first electrode 61 cover a portion of the PIN photodiode 52 and 62, respectively. The first electrodes 51 and 61 are made of transparent conductive materials, e.g. an ITO in a thickness about 50 nm.

The first insulation layer 91 servers as passivation film for the two photodiodes. Two through holes, 71 and 72 are made on insulation layer 91 to allow a metal layer 81 connecting together the bottom metal of the photodiode PD₁ and the top metal of the photodiode PD₂.

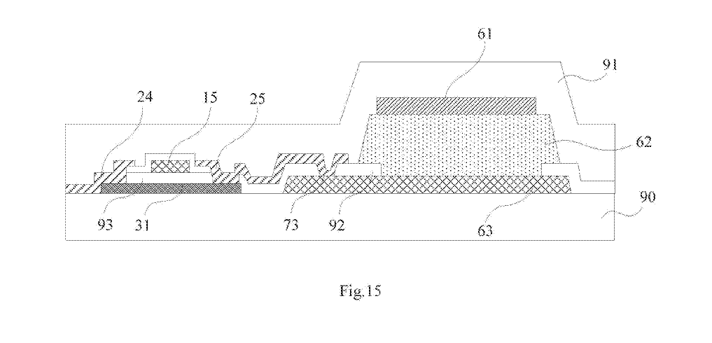

FIG. 15 shows a cross-sectional view of the photodiode PD₂ and the first reset transistor of the pixel shown in FIG. 13. As indicated in FIG. 15, layer 31 is the semiconductor thin film of the reset transistor M₁, comprising LTPS or metal oxide alloys or other semiconductor materials. Moreover, the metal oxide alloys include but not limited to the metal oxide In₂O₃, ZnO, Ga₂ O₃ or SnO₂. The gale insulator 93 and the second insulation layer 92 of the second photodiode PD₂ are formed in the same time. The source terminal 25 of the reset transistor M1 is connected to the bottom electrode of the second photodiode PD₂ through via hole 73. The drain terminal of the reset transistor M1 24 is connected to a reference voltage source 22 (as shown in FIG. 13).

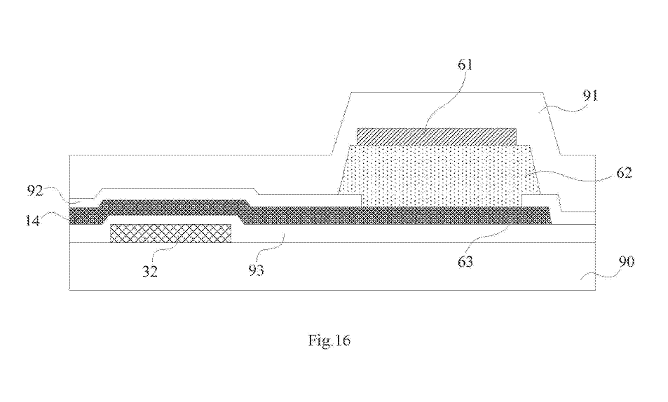

FIG. 16 shows a cross-sectional view of the photodiode D₂ and the amplifying transistor M₂, of the pixel shown in FIG. 13. As shown in FIG. 16, a bottom electrode 63 of the photodiode PD₂, a gate electrode 14 of the amplifying transistor M₂. The two electrodes 63 and 14 are formed at the same h the same conductive material such as Mo metal or polysilicon, and most importantly they are shorted together. In this configuration, potential changes at the photodiode terminal 63 will be applied to the amplifying transistor M₂.

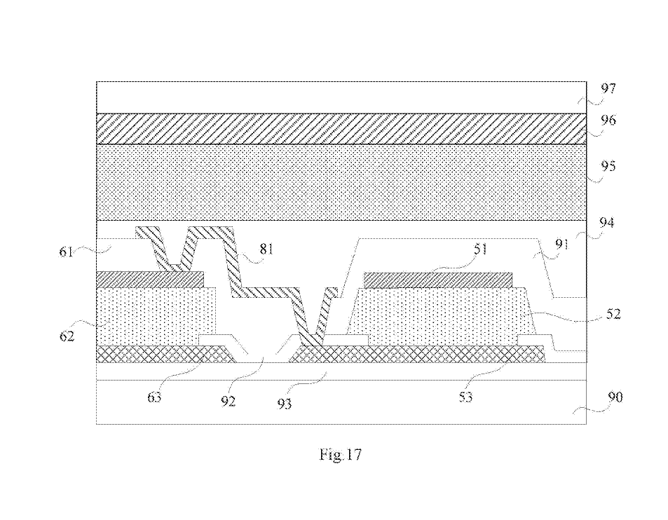

FIG. 17 shows a cross-sectional view of the pixel shown in FIG. 13. Comparing with FIG. 14, a multilayer structure is laminated on the photodiode chain for X-ray conversion purpose. As shown in FIG. 17, the multilayer structure includes an insulation layer 94, including Silicon Nitride or Silicon Oxide or their combinations, as barrier of air and moisture. Another embodiment includes a planarization layer in the multilayer structure in order to make surface smooth before deposition of subsequent layers. A radiation conversion layer 95 is formed on the insulation passivation layer 94, comprising scintillation film or fluorescent film to convert high energy radiations into visible light. The electronic radiations include X-ray, Gamma ray or other high-energy radiations or ions. In some embodiments, the scintillation film includes CsI(TI). In some embodiments, the scintillation film includes Gd₂O₂S. A visible light reflecting layer 96 is laminated on the conversion layer 95 for reflecting visible light back to the photodiodes underneath. The visible light reflecting layer 96, is made with an evaporated Aluminum film or other materials having high visible light reflectivity. On the reflecting layer 96, there is an additional protection layer 97, working with the reflecting layer 96, to block moisture and reactive gases penetrating into radiation conversion layer.

Furthermore, in some embodiments, the imaging sensor further includes a signal read out circuits and scanning circuits made on crystal silicon chips, or thin film circuits comprising amorphous silicon or polysilicon thin film on glass substrates. Electrostatic protection circuits, including TFTs, capacitors and resistors, are fabricated with the imaging sensor and in the peripheral area of the pixel array. In some embodiments, the substrate includes a glass substrate, a stainless substrate and a flexible substrate comprising organic materials. In some embodiments, an imaging sensor without the radiation conversion layer 95 is used for sensing visible light images.

In summary, each pixel of an imaging sensor of the present disclosure includes a photodiode chain comprising at least two photodiodes connected in series, and an amplifying transistor having a gate electrode connected to one of the terminals of the photodiode chain. With this pixel circuit configuration, total capacitance at the gate electrode of the amplifying transistor is reduced and then large voltage gain is obtained. The concept revealed in the present disclosure can be implemented into various imaging sensors, including flat panel imaging sensor for X-ray or Gamma ray image detection, and other non-visible light imaging sensors or visible light imaging sensors that where high sensitivity is required.

What is claimed is:

1. An imaging sensor including a pixel array having a plurality of pixels, the pixel comprising:
a photodiode chain comprising at least a first photodiode and a second photodiode connected in series, wherein the first terminal of the photodiode chain is connected to a first voltage source;
an amplifying transistor having a gate electrode connected to the second terminal of the photodiode chain;
a first reset transistor having a gate electrode connected to a second scan line, having a source electrode connected to the gate electrode of the amplifying transistor, having a drain electrode connected to a second voltage source; and
an output transistor having a gate electrode connected to a first scan line, and having a source electrode connected to the amplifying transistor, having a drain electrode connected to an output data line.

2. The imaging sensor of claim 1, wherein the pixel further includes a second reset transistor having a source electrode connected to a joint-node of the first photodiode and the second photodiode, having a drain electrode connected to a third voltage source, and having a gate electrode connected to the second scan line.

3. The imaging sensor of claim 2, wherein the transistors include PMOS transistors or NMOS transistors.

4. The imaging sensor of claim 2, wherein the first and the second reset transistors both comprise at least two polysilicon thin film transistors that which are connected in series.

5. The imaging sensor of claim 1, wherein the differences in bias voltage on each photodiode from an averaged bias voltage, defined by (V_{PD}−V_{DD})/N, is less than 30% of the averaged bias voltage, wherein the V_{PD} is the first voltage source, the V_{DD} is the second voltage source applied to the two terminals of the photodiode chain respectively, and N is the number of photodiode in the photodiode chain.

6. The imaging sensor of claim 1, wherein the pixel further includes:
a first insulation layer, formed on incident side of the first conducting layer, includes a first via and a second via, wherein the first via reaches the first electrode of the first photodiode and the second via reaches the second electrode of an adjacent photodiode; and
a second insulation layer, formed on incident side of the second conducting layer, wherein a portion of the second insulation layer covers the second electrode of the adjacent photodiode; and
a metal layer configured to conduct the first electrode of the photodiode and the second electrode of the adjacent photodiode via the first via and the second via.

7. The imaging sensor of claims 1, wherein the transistors in the pixel are made of semiconductor thin film, including amorphous silicon, polysilicon, metal oxide alloys comprising the metal oxide In₂O₃, ZnO, Ga₂O₃ or SnO₂.

8. The imaging sensor of claims 2, wherein the transistors in the pixel are made of semiconductor thin film, including amorphous silicon, polvsilicon, metal oxide alloys comprising the metal oxide In₂O₃, ZnO, Ga₂O₃ or SnO₂.

9. The imaging sensor of claim 1, wherein the difference in effective light receiving areas of any two photodiodes is less than 50% of the effective light-receiving area of any of the photodiode in the photodiode chain.

10. The imaging sensor of claim 1, wherein the first terminal of the photodiode chain is connected the first voltage source through a data output line of the pixel.
